(19) United States
(12) Patent Application Publication
(10) Pub. No.: US 2026/0080932 A1
(43) Pub. Date: Mar. 19, 2026

(54) CONTROL CIRCUIT AND MEMORY

(71) Applicant: CXMT Corporation, Hefei City (CN)

(72) Inventors: Yanian SHAO, Hefei City (CN); Yoonjoo EOM, Hefei City (CN); Jiajin SONG, Hefei City (CN)

(73) Assignee: CXMT Corporation, Hefei City (CN)

(21) Appl. No.: 19/395,391

(22) Filed: Nov. 20, 2025

Related U.S. Application Data
(63) Continuation of application No. PCT/CN2024/094422, filed on May 21, 2024.

(30) Foreign Application Priority Data
May 24, 2023 (CN) 202310613574.5

(51) Int. Cl. G11C 11/4076; G11C 11/408; G11C 11/4093; H03K 19/20

(52) U.S. Cl. CPC G11C 11/4076; G11C 11/4087; G11C 11/4093; H03K 19/20

(57) ABSTRACT

A control circuit includes: an input sampling circuit, configured to perform sampling processing on an initial command address signal based on a first clock signal to generate an intermediate command address signal; a gating generation circuit, configured to generate a first gating enable signal based on the intermediate command address signal and perform pulse width adjustment on the first gating enable signal based on a reset signal to generate a first gating signal; and a clock control circuit, configured to perform control processing on a second clock signal based on the first gating signal to generate a command clock signal. There is an association relationship between the level state of the first gating enable signal and the intermediate command address signal.

### CROSS-REFERENCE TO RELATED APPLICATION(S)

This application is a continuation of International Patent Application No. PCT/CN2024/094422 filed on May 21, 2024, which claims priority to Chinese Patent Application No. 202310613574.5 filed on May 24, 2023. The disclosures of the above-referenced applications are hereby incorporated by reference in their entirety.

### TECHNICAL FIELD

The present disclosure relates to the field of semiconductor technologies, and in particular, relates to a control circuit and a memory.

### BACKGROUND

With the continuous development of semiconductor technology, there are increasingly higher demands for data transmission speed when manufacturing and using devices like computers. To achieve faster data transmission speeds, a series of devices have emerged that can transmit data at a double data rate (Double Data Rate, DDR), such as certain types of memory.

In dynamic random access memory (Dynamic Random Access Memory, DRAM) chips, concerning the on die termination (On Die Termination, ODT) circuit, even when no ODT command arrives, the existing ODT circuit will still release clock signals related to the ODT command. This causes logic gates in the ODT circuit to constantly switch levels, which consumes a large amount of current, thereby increasing the power consumption of the DRAM chip.

### SUMMARY

The present disclosure provides a control circuit and a memory.

The technical solutions of the present disclosure are implemented as follows:

In a first aspect, the embodiments of the present disclosure provide a control circuit. The control circuit includes an input sampling circuit, a gating generation circuit, and a clock control circuit.

The input sampling circuit is configured to receive an initial command address signal and a first clock signal and perform sampling processing on the initial command address signal based on the first clock signal to generate an intermediate command address signal.

The gating generation circuit is configured to receive the intermediate command address signal and a reset signal, generate a first gating enable signal based on the intermediate command address signal, and perform pulse width adjustment on the first gating enable signal based on the reset signal to generate a first gating signal. Additionally, the pulse width of the first gating signal is greater than the pulse width of the first gating enable signal.

The clock control circuit is configured to receive the first gating signal and a second clock signal and perform control processing on the second clock signal based on the first gating signal to generate a command clock signal.

There is an association relationship between the level state of the first gating enable signal and the intermediate command address signal. Additionally, when the first gating signal is in a first level state, the frequency of the command clock signal is the same as that of the second clock signal; when the first gating signal is in a second level state, the second clock signal is blocked so that the command clock signal is at a low level.

In some embodiments, the first level state is a high-level state, and the second level state is a low-level state.

In some embodiments, the gating generation circuit includes a decoding sub-circuit and an SR latch.

The decoding sub-circuit is configured to receive the intermediate command address signal and perform the first decoding processing on the intermediate command address signal to obtain the first gating enable signal. Additionally, the first gating enable signal has a preset delay time compared to the intermediate command address signal.

The SR latch is configured to receive the first gating enable signal and the reset signal and perform pulse width adjustment on the first gating enable signal based on the reset signal to generate the first gating signal.

If it is determined, based on the intermediate command address signal, that a first command is present, a level state of the first gating enable signal is at a low level; if it is determined, based on the intermediate command address signal, that the first command is not present, the level state of the first gating enable signal is at a high level. The first command includes at least one of the following: a mode register read command (MRR), a write command (WR), a write with auto pre-charge command (WRA), and a read command (RD).

In some embodiments, the SR latch includes a first NAND gate and a second NAND gate.

A first input terminal of the first NAND gate is configured to receive the first gating enable signal, and a second input terminal of the first NAND gate is connected to an output terminal of the second NAND gate; a first input terminal of the second NAND gate is connected to an output terminal of the first NAND gate, and a second input terminal of the second NAND gate is configured to receive the reset signal; the output terminal of the first NAND gate is configured to output the first gating signal.

In some embodiments, the control circuit further includes a command decoding circuit.

The command decoding circuit is configured to receive the intermediate command address signal and a third clock signal, perform second decoding processing on the intermediate command address signal to obtain a decoded signal, and perform sampling and delay processing based on the third clock signal and the decoded signal to obtain a first command signal.

In some embodiments, the command decoding circuit includes a decoding module, a sampling sub-module, and a first delay module. Additionally, an output terminal of the decoding module is connected to an input terminal of the sampling sub-module, and an output terminal of the sampling sub-module is connected to an input terminal of the first delay module.

The decoding module is configured to receive the intermediate command address signal and perform the second decoding processing on the intermediate command address signal to obtain the decoded signal.

The sampling sub-module is configured to receive the decoded signal and the third clock signal and perform sampling processing on the decoded signal based on the third clock signal to obtain an intermediate command signal.

The first delay module is configured to receive the intermediate command signal and perform first delay processing on the intermediate command signal to obtain the first command signal.

In some embodiments, the control circuit further includes an output sampling circuit and a delay shift circuit.

The output sampling circuit is configured to receive the first command signal and the command clock signal and perform sampling processing on the first command signal based on the command clock signal to obtain a second command signal.

The delay shift circuit is configured to perform sampling and shifting processing on the second command signal to obtain a third command signal. The third command signal is used to control the resistance switching of a termination resistance.

In some embodiments, the output sampling circuit includes an output flip-flop.

A clock terminal of the output flip-flop is configured to receive the command clock signal, an input terminal of the output flip-flop is configured to receive the first command signal, and a first output terminal of the output flip-flop is configured to output the second command signal.

The first output terminal of the output flip-flop is configured to reflect a value at the input terminal of the output flip-flop after being sampled by the command clock signal.

In some embodiments, the control circuit further includes a clock delay circuit, and the clock delay circuit includes a second delay module, a third delay module, and a fourth delay module.

The second delay module is configured to receive a first initial clock signal and perform second delay processing on the first initial clock signal to obtain the first clock signal.

The third delay module is configured to receive the first initial clock signal and perform third delay processing on the first initial clock signal to obtain the third clock signal.

The fourth delay module is configured to receive a second initial clock signal and perform fourth delay processing on the second initial clock signal to obtain the second clock signal.

In some embodiments, the control circuitry further includes a clock buffer circuit.

The clock buffer circuit is configured to receive an initial clock signal and generate the first initial clock signal and the second initial clock signal based on the initial clock signal.

The frequency and the phase of the first initial clock signal are the same as the frequency and the phase of the second initial clock signal.

In some embodiments, the clock control circuit includes a fifth delay module.

The fifth delay module is configured to receive the first gating signal and the second clock signal and perform a NAND logic operation and fifth delay processing on the first gating signal and the second clock signal to obtain the command clock signal.

In some embodiments, the fifth delay module includes a third NAND gate and an inverting module.

A first input terminal of the third NAND gate is configured to receive the first gating signal, a second input terminal of the third NAND gate is configured to receive the second clock signal, and an output terminal of the third NAND gate is configured to output an intermediate clock signal.

An input terminal of the inverting module is connected to the output terminal of the third NAND gate for performing delay and inversion processing on the intermediate clock signal and outputting the command clock signal through an output terminal of the inverting module.

In some embodiments, the inverting module is composed of an odd number of NOT gates connected in series.

In some embodiments, the sum of the delay time corresponding to the first delay processing and the delay time corresponding to the third delay processing is greater than the sum of the preset delay time, the delay time corresponding to the second delay processing, and the delay time corresponding to the fifth delay processing, such that the time when the command clock signal reaches the output flip-flop is earlier than the time when the first command signal reaches the output flip-flop.

In a second aspect, the embodiments of the present disclosure provide a memory. The memory includes at least the control circuit as described in any of the first aspect.

The embodiments of the present disclosure provide a control circuit and a memory. In the control circuit, an input sampling circuit is configured to receive an initial command address signal and a first clock signal and perform sampling processing on the initial command address signal based on the first clock signal to generate an intermediate command address signal; a gating generation circuit is configured to receive the intermediate command address signal and a reset signal, generate a first gating enable signal based on the intermediate command address signal, and perform pulse width adjustment on the first gating enable signal based on the reset signal to generate a first gating signal, the pulse width of the first gating signal being greater than the pulse width of the first gating enable signal; and a clock control circuit is configured to receive the first gating signal and a second clock signal and perform control processing on the second clock signal based on the first gating signal to generate a command clock signal. There is an association relationship between the level state of the first gating enable signal and the intermediate command address signal. This not only ensures that the first gating signal is no longer affected by the chip select signal but also, since the intermediate command address signal can also determine whether the ODT command is in an operational state, ensures that the first gating signal is in the first level state only when the ODT command is in operation. In this way, when the ODT command is in a non-operational state, the first gating signal at this point is in a second level state, allowing the second clock signal to be blocked so that the command clock signal is at a low level. This can avoid the phenomenon of constant level switching of a logic gate in an ODT circuit when the ODT command is not needed, thereby effectively preventing extra current consumption, achieving the purpose of saving current and reducing memory power consumption, and ultimately improving memory performance.

### BRIEF DESCRIPTION OF DRAWINGS

FIG. 1 is a schematic structural diagram of an ODT function circuit;

FIG. 2 is a schematic diagram of signal timing of an ODT function;

FIG. 3 is a first schematic diagram of a composition structure of a control circuit according to an embodiment of the present disclosure;

FIG. 4 is a schematic diagram of a composition structure of an input sampling circuit according to an embodiment of the present disclosure;

FIG. 5 is a schematic diagram of a composition structure of a gating generation circuit according to an embodiment of the present disclosure;

FIG. 6 is a schematic diagram of a composition structure of a command decoding circuit according to an embodiment of the present disclosure;

FIG. 7 is a second schematic diagram of a composition structure of a control circuit according to an embodiment of the present disclosure;

FIG. 8 is a schematic diagram of a composition structure of an output sampling circuit according to an embodiment of the present disclosure;

FIG. 9 is a third schematic diagram of a composition structure of a control circuit according to an embodiment of the present disclosure;

FIG. 10 is a schematic diagram of a composition structure of a clock control circuit according to an embodiment of the present disclosure;

FIG. 11 is a detailed schematic structural diagram of a control circuit according to an embodiment of the present disclosure;

FIG. 12 is a first schematic diagram of signal timing of a control circuit according to an embodiment of the present disclosure;

FIG. 13 is a second schematic diagram of signal timing of a control circuit according to an embodiment of the present disclosure;

FIG. 14 is a schematic flowchart of a control method according to an embodiment of the present disclosure; and

FIG. 15 is a schematic diagram of a composition structure of a memory according to an embodiment of the present disclosure.

### DESCRIPTION OF EMBODIMENTS

The technical solutions in the embodiments of the present disclosure will be clearly and completely described below with reference to the drawings in the embodiments of the present disclosure. It can be understood that the specific embodiments described herein are merely illustrative of a related application and are not intended to limit the application. In addition, it should be noted that for the convenience of description, only the portions relevant to the related applications are shown in the drawings.

Unless otherwise defined, all technical and scientific terms used herein have the same meaning as commonly understood by those skilled in the art to which the present disclosure belongs. The terms used herein are for the purpose of describing the embodiments of the present disclosure only and are not intended to limit the present disclosure.

In the following description, reference is made to “some embodiments” which describe subsets of all possible embodiments, but it can be understood that “some embodiments” may be the same subset or different subsets of all possible embodiments, and may be combined with each other without conflict.

It should be noted that the terms “first\second\third” referred to in the embodiments of the present disclosure are merely used for distinguishing similar objects and do not represent a specific ordering for the objects. It is understandable that “first\second\third” may be subjected to interchange of a specific order or sequence if permitted, such that the embodiments of the present disclosure described herein can be implemented in an order other than that shown or described herein.

Before further detailed description of the embodiments of the present disclosure, the nouns and terms referred to in the embodiments of the present disclosure are explained, and the nouns and terms referred to in the embodiments of the present disclosure are applicable to the following explanations:
Dynamic Random Access Memory (Dynamic Random Access Memory, DRAM);
Double Data Rate (Double Data Rate, DDR);
Double Data Rate 3 (Double Data Rate, DDR3);
Double Data Rate 4 (Double Data Rate, DDR4);
Double Data Rate 5 (Double Data Rate, DDR5);
On Die Termination (On Die Termination, ODT);
Termination Resistance (Termination Resistance, RTT);
Command (CMD);
Data (Data, DQ);
Chip Select signal (Chip Select, CS);
Mode Register Read command (Mode Register Read, MRR);
Write command (Write, WR);
Read command (Read, RD);
Write with auto pre-charge command (Write/Auto Pre-charge, WRA);
Column Address Strobe Write Latency (CAS Write Latency, CWL);
Burst Length (Burst Length, BL);
Mode Register Setting (Mode Register Setting, MRS);
High level (High, H);
Low level (Low, L);
Valid level (Valid, V);
D Flip-Flop (Data Flip-Flop or Delay Flip-Flop, DFF);
Central Processing Unit (Central Processing Unit, CPU).

With the rapid development of semiconductor technology, the transmission rate of signals is becoming faster, leading to increasingly prominent signal integrity issues. During the propagation of high-speed signals, to better improve the signal integrity of data, an ODT resistance is introduced separately in the design of DDR3, DDR4, and DDR5. This approach uses the ODT resistance for impedance matching of the transmission line, reducing reflection and energy loss during signal transmission, thereby ensuring the integrity of the signals received at the receiving end.

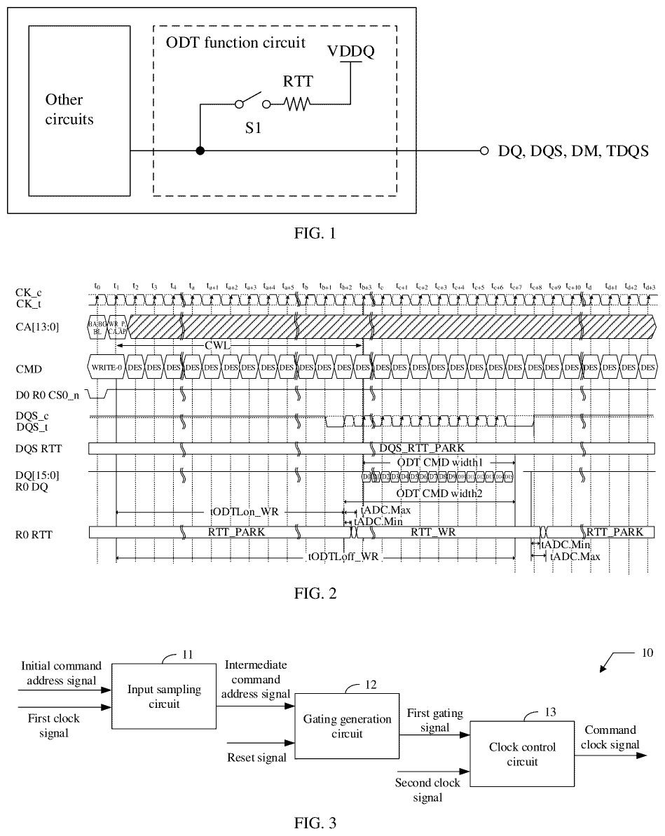

Taking DDR5 DRAM as an example, DDR5 DRAM supports the ODT function, which can adjust the termination resistance of each device's DQ, DQS_t/c, DM_n, and TDQS_t/c ports through ODT pin control, write commands, or by setting a default resistance via a mode register. In addition, the purpose of the ODT function is to reduce reflection and effectively improve signal integrity on the memory interface by allowing the controller to independently control the termination resistance of all or any one of the DRAMs. FIG. 1 illustrates a schematic structural diagram of an ODT function circuit according to the related art. In FIG. 1, the ODT function circuit may include at least a switch S1, a termination resistance RTT, and a power supply VDDQ. One end of the switch S1 is connected to one end of the termination resistance RTT, the other end of the termination resistance RTT is connected to the power supply VDDQ, and the other end of the switch S1 is connected to other circuits as well as the DQ, DQS, DM, and TDQS ports. It should be noted that DQS may be a pair of differential data strobe signals DQS_t and DQS_c, and TDQS may be a pair of differential data strobe signals TDQS_t and TDQS_c.

In addition, the switch S1 in FIG. 1 is controlled by an ODT control logic. The ODT control logic includes input from an external ODT pin, mode register configuration, and other control information. The value of RTT is controlled by the configuration information in a mode register. In addition, if in a self-refresh mode or after the mode register configuration disables RTT NOM, the control of the ODT pin is ignored.

Exemplarily, FIG. 2 illustrates a schematic diagram of signal timing of an ODT function, specifically a schematic diagram of control timing for the ODT function during a write operation in DDR5. As shown in FIG. 2, when DDR5 receives a command (CMD), the command needs to be transmitted to a DQ end to control the change in the resistance of RTT. When DDR5 receives a write command, the resistance of RTT needs to switch from RTT_PARK to RTT_WR. That is, when the resistance of RTT is in the RTT_PARK phase, the DQ end does not receive data. When the write command is transmitted to the DQ end, the resistance of RTT at this point switches to the RTT_WR phase, and the DQ end receives and writes data. That is, before the DQ end receives data, when the resistance of RTT switches from RTT_PARK to RTT_WR, it is necessary to wait for tODTLon_WR preset clock cycles after the write command. Here, tODTLon_WR=CWL+ODTLon_WR_offset, where ODTLon_WR_offset represents the adjustment value for the tODTLon_WR parameter sent by a controller. After the DQ end finishes receiving data, when the resistance of RTT switches back from RTT_WR to RTT_PARK, it is necessary to wait for tODTLoff_WR preset clock cycles after the write command. Here, tODTLoff_WR=CWL+BL/2+ODTLoff_WR_offset, where ODTLoff_WR_offset represents the adjustment value for the tODTLoff_WR parameter sent by the controller. In addition, the switch in the resistance of RTT does not occur immediately but requires time to change, and the time for switching the resistance of RTT is represented by tADC. A maximum value and a minimum value can be set for tADC, which are respectively expressed as: tADC.Max and tADC.Min.

Furthermore, the technical specifications of DDR5 stipulate that DDR5 usually adopts a half-rate (Half Rate) clock scheme to achieve high-frequency (High Frequency, HF) operation above 4800 Megabits per second (Megabits per second, Mbps). Although such an ODT circuit can prevent peak currents generated during high-frequency operation, it consumes higher standby currents. Therefore, there is a need for a clock gating scheme that can reduce current consumption.

Based on this, a control circuit is provided according to the embodiments of the present disclosure. There is an association relationship between the level state of a first gating enable signal and an intermediate command address signal. When the first gating signal is in a first level state, the frequency of the command clock signal is the same as that of the second clock signal; when the first gating signal is in a second level state, the second clock signal is blocked so that the command clock signal is at a low level. In this way, since the level state of the first gating enable signal only has an association relationship with the intermediate command address signal, the first gating enable signal is no longer affected by the chip select signal, and at the same time, the intermediate command address signal can also determine whether the ODT command is in an operational state, such that the first gating signal is in the first level state only when the ODT command is in operation, during which the frequency of the command clock signal is the same as that of the second clock signal. When the ODT command is in a non-operational state, the first gating signal at this point is in a second level state, allowing the second clock signal to be blocked so that the command clock signal is at a low level. This can avoid the phenomenon of constant level switching of a logic gate in an ODT circuit when the ODT command is not needed, thereby effectively preventing extra current consumption, achieving the purpose of saving current and reducing memory power consumption, and ultimately improving memory performance.

The embodiments of the present disclosure are described in detail below with reference to the drawings.

In an embodiment of the present disclosure, referring to FIG. 3, a schematic diagram of a composition structure of a control circuit according to an embodiment of the present disclosure is illustrated. As shown in FIG. 3, the control circuit 10 may include an input sampling circuit 11, a gating generation circuit 12, and a clock control circuit 13.

The input sampling circuit 11 is configured to receive an initial command address signal and a first clock signal and perform sampling processing on the initial command address signal based on the first clock signal to generate an intermediate command address signal.

The gating generation circuit 12 is configured to receive the intermediate command address signal and a reset signal, generate a first gating enable signal based on the intermediate command address signal, and perform pulse width adjustment on the first gating enable signal based on the reset signal to generate a first gating signal. The pulse width of the first gating signal is greater than that of the first gating enable signal.

The clock control circuit 13 is configured to receive the first gating signal and a second clock signal and perform control processing on the second clock signal based on the first gating signal to generate a command clock signal.

In the embodiment of the present disclosure, there is an association relationship between the level state of the first gating enable signal and the intermediate command address signal. Moreover, when the first gating signal is in a first level state, the frequency of the command clock signal is the same as that of the second clock signal; when the first gating signal is in a second level state, the second clock signal is blocked so that the command clock signal is at a low level.

It should be noted that in the embodiment of the present disclosure, the control circuit 10 can be applied to a memory. The memory may be, for example, a static random access memory (static random access memory, SRAM), a dynamic random access memory (dynamic random access memory, DRAM), a synchronous dynamic random access memory (synchronous dynamic random access memory, SDRAM), or a double data rate SDRAM (double data rate SDRAM, DDR SDRAM), which is not specifically limited herein.

It should be further noted that in the embodiment of the present disclosure, the control circuit 10 can specifically be an input clock control circuit relating to the ODT command. Here, an initial command address signal related to the ODT command is used to generate a first gating signal. The first gating signal will only release a clock signal when the ODT command arrives, thereby achieving the purpose of saving current.

It should be further noted that in the embodiment of the present disclosure, the initial command address signal is a signal obtained by combining a plurality of command address signals. Exemplarily, the plurality of command address signals may include CA0, CA1, and CA2. It should be noted that the initial command address signal not only includes CA0, CA1, and CA2 but may also include other initial command address signals, such as CA3, CA4, or CA5, which is not specifically limited.

It should be further noted that in the embodiment of the present disclosure, the clock cycles of the first clock signal and the second clock signal are equal, and may be represented by tck. The reset signal may be represented by RST, the first gating enable signal may be represented by ODT_Gating_EN, and the first gating signal may be represented by ODT_Gating.

It should be further noted that in the embodiment of the present disclosure, pulse width adjustment is performed on the first gating enable signal based on the reset signal, such that the pulse width of the generated first gating signal is greater than that of the first gating enable signal. The pulse width may be referred to as “PW”. In this way, when the first gating signal is in the first level state, the command clock signal generated based on the first gating signal has a sufficiently long clock period to generate an ODT command that ultimately meets the requirement. Moreover, the pulse width of the finally generated ODT command can cover the entire data writing process of DQ.

It should be further noted that in the embodiment of the present disclosure, when the first gating signal is in the second level state, the clock signal related to the ODT command will be turned off, that is, the second clock signal is blocked in the ODT circuit, resulting in the command clock signal being at a low level. Since the command clock signal is at a low level, the clock-related logic gate in the ODT circuit will not undergo level switching, thereby achieving the purpose of saving current and reducing power consumption. Here, the clock-related logic gate refers to all logic gates on the transmission path of the ODT circuit that need to use the command clock signal (not shown in the figure). It is understandable that the level switching of the logic gate refers to the constant change of the input clock signal at the logic gate between high and low levels, which consequently leads to corresponding continuous changes in the output level state of the logic gate, thus consuming current. In addition, in the embodiment of the present disclosure, the logic gate may include a flip-flop, an AND gate, an OR gate, a NOT gate, a NAND gate, a NOR gate, or the like, which is not specifically limited.

Furthermore, in some embodiments, the first level state is a high-level state, and the second level state is a low-level state.

It should be noted that in the embodiment of the present disclosure, a high-level state may be represented as logic 1; a low-level state may be represented as logic 0.

It should be further noted that in the embodiment of the present disclosure, when the first gating signal is in a high-level state, i.e., when ODT_Gating=1, the first gating signal is in an active state, and a command clock signal can be generated based on the second clock signal. In this case, the second clock signal will not be blocked, and there is a clock input at the clock terminal of the ODT circuit. When the first gating signal is in a low-level state, i.e., when ODT_Gating=0, the second clock signal will be blocked, resulting in the command clock signal being at a low level. As a result, there is no clock input at the clock terminal of the ODT circuit, that is, the clock-related logic gate inside the ODT circuit will not undergo level switching.

In some embodiments, the initial command address signal includes a first initial command address signal, a second initial command address signal, and a third initial command address signal.

It should be noted that in the embodiment of the present disclosure, the first initial command address signal may be represented by CA0, the second initial command address signal may be represented by CA1, and the third initial command address signal may be represented by CA2. Table 1 illustrates the relevant specifications regarding CA0, CA1, and CA2 in DDR5. CS_n represents the chip select signal, H represents the high-level state, L represents the low-level state, V represents the valid level state, and C2, C3, and C4 represent address information.

It should be further noted that in the embodiment of the present disclosure, the initial command address signal includes not only CA0, CA1, and CA2 but may also include other initial command address signals, which are not specifically limited. It is understandable that CA0, CA1, and CA2 are the three key initial command address signals for decoding to obtain the first gating signal, which is why Table 1 exemplifies the relevant specifications regarding CA0, CA1, and CA2.

TABLE 1

| | | | Initial command | | |
|---|---|---|---|---|---|
| | Abbreviation | CS_{—} | address signal | | |
| Function (Function) | (Abbreviation) | n | CA0 | CA1 | CA2 |
| Mode register read | MRR | L | H | L | H |
| command (Mode Register | | H | L | L | V |
| Read) | | | | | |
| Write command (Write) | WR | L | H | L | H |
| | | H | V | C3 | C4 |
| Write with auto pre-charge | WRA | L | H | L | H |
| command | | H | V | C3 | C4 |
| (Write/Auto Pre-charge) | | | | | |
| Read command (Read) | RD | L | H | L | H |
| | | H | C2 | C3 | C4 |

It should be further noted that when any of the following commands arrive-such as a mode register read command, a write command, a write with auto pre-charge command, or a read command—it means that the ODT circuit is in an operational state. Exemplarily, taking CA0, CA1, and CA2 as examples, the level states of CA0, CA1, and CA2 in Table 1 vary for different commands. In addition, the first gating enable signal is related to whether the ODT circuit is operating. Therefore, in the embodiment of the present disclosure, CA0, CA1, and CA2 may be used to characterize the level state of the first gating enable signal. In other words, there is an association relationship between the level state of the first gating enable signal and the initial command address signal.

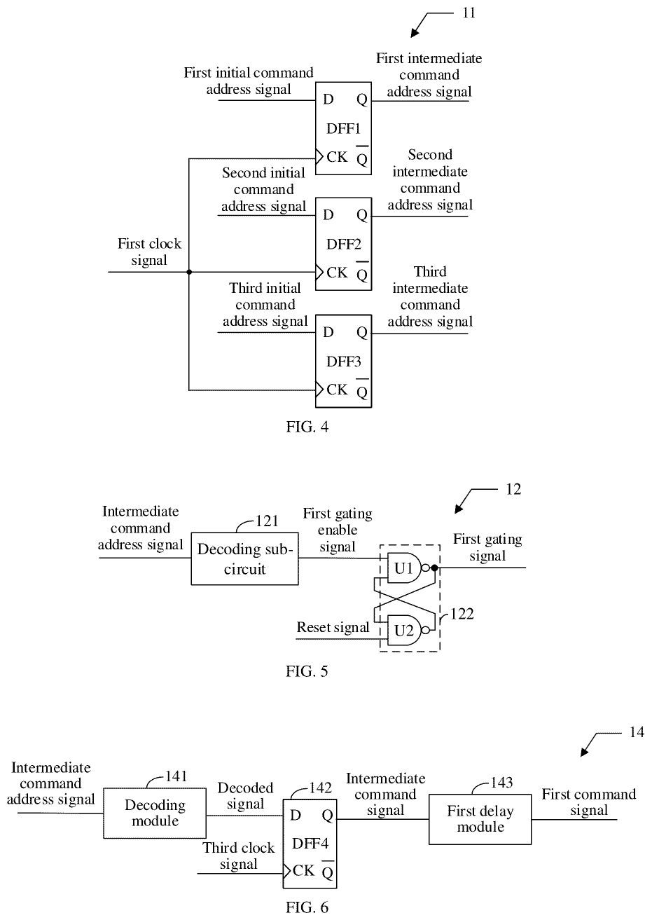

Furthermore, for the input sampling circuit 11, the input sampling circuit 11 may include a plurality of flip-flops for receiving and performing sampling processing on all the initial command address signals. Exemplarily, taking the example where the initial command address signal includes a first initial command address signal, a second initial command address signal, and a third initial command address signal, referring to FIG. 4, the input sampling circuit 11 may include a first flip-flop DFF1, a second flip-flop DFF2, and a third flip-flop DFF3.

The first flip-flop DFF1 is configured to receive the first initial command address signal and a first clock signal and perform sampling processing on the first initial command address signal based on the first clock signal to obtain a first intermediate command address signal.

The second flip-flop DFF2 is configured to receive the second initial command address signal and the first clock signal and perform sampling processing on the second initial command address signal based on the first clock signal to obtain a second intermediate command address signal.

The third flip-flop DFF3 is configured to receive the third initial command address signal and the first clock signal and perform sampling processing on the third initial command address signal based on the first clock signal to obtain a third intermediate command address signal.

The intermediate command address signals are composed of the first intermediate command address signal, the second intermediate command address signal, and the third intermediate command address signal.

It should be noted that in the embodiment of the present disclosure, a first output terminal of the first flip-flop DFF1 is configured to reflect a value at an input terminal of the first flip-flop DFF1 after being sampled by the first clock signal. A first output terminal of the second flip-flop DFF2 is configured to reflect a value at an input terminal of the second flip-flop DFF2 after being sampled by the first clock signal. A first output terminal of the third flip-flop DFF3 is configured to reflect a value at an input terminal of the third flip-flop DFF3 after being sampled by the first clock signal.

It should be further noted that in the embodiment of the present disclosure, the first flip-flop DFF1, the second flip-flop DFF2, and the third flip-flop DFF3 may be D flip-flops (Data Flip-Flop or Delay Flip-Flop, DFF). A D flip-flop is an information storage device with memory functionality and two stable states, which serves as the most basic logical unit for constituting various timing circuits and is also an important unit circuit in a digital logic circuit. Here, a D flip-flop has two stable states, “0” and “1”, and can toggle from one stable state to another stable state under the influence of the signal received at the clock terminal.

It should be further noted that in the embodiment of the present disclosure, the first flip-flop DFF1, the second flip-flop DFF2, and the third flip-flop DFF3 may each include a clock terminal (CK), an input terminal (D), a first output terminal (Q), and a second output terminal (Q). Additionally, the first flip-flop DFF1, the second flip-flop DFF2, and the third flip-flop DFF3 may also include a set terminal (SET) and a reset terminal (RST), although these are not shown in the figures.

It should be further noted that in the embodiment of the present disclosure, the input sampling circuit 11 can perform sampling processing on the initial command address signal based on the first clock signal to generate the intermediate command address signal. Specifically, there is an association relationship between the level state of the first gating enable signal and the intermediate command address signal.

In some embodiments, for a gating generation circuit 12, referring to FIG. 5, the gating generation circuit 12 may include a decoding sub-circuit 121 and an SR latch 122.

The decoding sub-circuit 121 is configured to receive an intermediate command address signal and perform first decoding processing on the intermediate command address signal to obtain a first gating enable signal. The first gating enable signal has a preset delay time compared to the intermediate command address signal.

The SR latch 122 is configured to receive the first gating enable signal and a reset signal and perform pulse width adjustment on the first gating enable signal based on the reset signal to generate a first gating signal.

It should be noted that in the embodiment of the present disclosure, if it is determined, based on the intermediate command address signal, that a first command is present, the level state of the first gating enable signal is at a low level. If it is determined, based on the intermediate command address signal, that the first command is not present, the level state of the first gating enable signal is at a high level.

The first command may include at least one of the following: a mode register read command (MRR), a write command (WR), a write with auto pre-charge command (WRA), and a read command (RD).

It should be further noted that in the embodiment of the present disclosure, the decoding sub-circuit 121 may be represented by G7, and the preset delay time is also represented by G7. When any command among MRR, WR, WRA, and RD appears, the decoding sub-circuit 121 will output the first gating enable signal.

It should be further noted that in the embodiment of the present disclosure, the level state of the first gating enable signal can be determined based on the intermediate command address signal. Specifically, if any command among MRR, WR, WRA, and RD is decoded based on the intermediate command address signal, the level state of the first gating enable signal is at a low level; if it is not possible to decode MRR, WR, WRA, or RD based on the intermediate command address signal, the level state of the first gating enable signal is at a high level.

It should be further noted that in the embodiment of the present disclosure, MRR, WR, WRA, or RD in Table 1 requires the use of termination resistance for reflection, thus necessitating the generation of an ODT command to control the switching of the resistance of the termination resistance. That is, determining whether a first command has arrived based on the intermediate command address signal will result in the first gating enable signal switching to being at a low level, regardless of which first command arrives.

It should be further noted that in the embodiment of the present disclosure, pulse width adjustment of the first gating enable signal is performed by the SR latch 122 based on the reset signal, and the pulse width of the generated first gating signal is greater than that of the first gating enable signal. Exemplarily, if the delay time between the falling edge of the level of the first gating enable signal and the change in level of the reset signal (from high level to low level) is 128 tck, then the pulse width of the first gating signal is 128 tck. Here, taking the write command as an example, 128 tck can ensure that there is a clock signal during the entire write delay time, and during this period, the delay processing of the write command signal can be completed even when using the maximum write delay time. That is, within 128 tck, it is possible to obtain the ODT command that meets the requirement for switching the resistance to control the termination resistance, thereby better satisfying the ODT delay requirement.

Furthermore, in some embodiments, for the SR latch 122, as shown in FIG. 5, the SR latch 122 includes a first NAND gate U1 and a second NAND gate U2.

A first input terminal of the first NAND gate U1 is configured to receive a first gating enable signal, and a second input terminal of the first NAND gate U1 is connected to an output terminal of the second NAND gate U2. A first input terminal of the second NAND gate U2 is connected to an output terminal of the first NAND gate U1, and a second input terminal of the second NAND gate U2 is configured to receive a reset signal. The output terminal of the first NAND gate U1 is configured to output a first gating signal.

It should be noted that in the embodiment of the present disclosure, pulse width adjustment of the first gating enable signal is performed by the SR latch 122 based on the reset signal to obtain the first gating signal. Specifically, the first input terminal of the first NAND gate U1 serves as the first input terminal of the SR latch 122 and is configured to receive the first gating enable signal; the second input terminal of the second NAND gate U2 serves as the second input terminal of the SR latch 122 and is configured to receive the reset signal; the output terminal of the first NAND gate U1 serves as the output terminal of the SR latch 122 and is configured to output the first gating signal.

In some embodiments, the control circuit may further include a command decoding circuit 14.

The command decoding circuit 14 is configured to receive an intermediate command address signal and a third clock signal, perform second decoding processing on the intermediate command address signal to obtain a decoded signal, and perform sampling and delay processing based on the third clock signal and the decoded signal to obtain a first command signal.

Furthermore, in some embodiments, for the command decoding circuit 14, referring to FIG. 6, the command decoding circuit 14 includes a decoding module 141, a sampling sub-module 142, and a first delay module 143. Moreover, an output terminal of the decoding module 141 is connected to an input terminal of the sampling sub-module 142, and an output terminal of the sampling sub-module 142 is connected to an input terminal of the first delay module 143.

The decoding module 141 is configured to receive an intermediate command address signal and perform second decoding processing on the intermediate command address signal to obtain a decoded signal.

The sampling sub-module 142 is configured to receive the decoded signal and a third clock signal and perform sampling processing on the decoded signal based on the third clock signal to obtain an intermediate command signal.

The first delay module 143 is configured to receive the intermediate command signal and perform first delay processing on the intermediate command signal to obtain a first command signal.

It should be noted that in the embodiment of the present disclosure, the decoding module 141 may be represented by G3; the first delay module 143 may be represented by G5, and the delay time corresponding to the first delay processing is also represented by G5.

It should be further noted that in the embodiment of the present disclosure, the decoded signal is the first command, i.e., a specific command among MRR, WR, WRA, and RD. That is, the decoding module 141 can decode a specific command, such as WR.

Furthermore, in some embodiments, for the sampling sub-module 142, as shown in FIG. 6, the sampling sub-module 142 may include a fourth flip-flop DFF4.

A clock terminal of the fourth flip-flop DFF4 is configured to receive a third clock signal, an input terminal of the fourth flip-flop DFF4 is configured to receive a decoded signal, and a first output terminal of the fourth flip-flop DFF4 is configured to output an intermediate command signal.

The first output terminal of the fourth flip-flop DFF4 is configured to reflect a value at the input terminal of the fourth flip-flop DFF4 after being sampled by the third clock signal.

It should be noted that in the embodiment of the present disclosure, the fourth flip-flop DFF4 may be a D flip-flop.

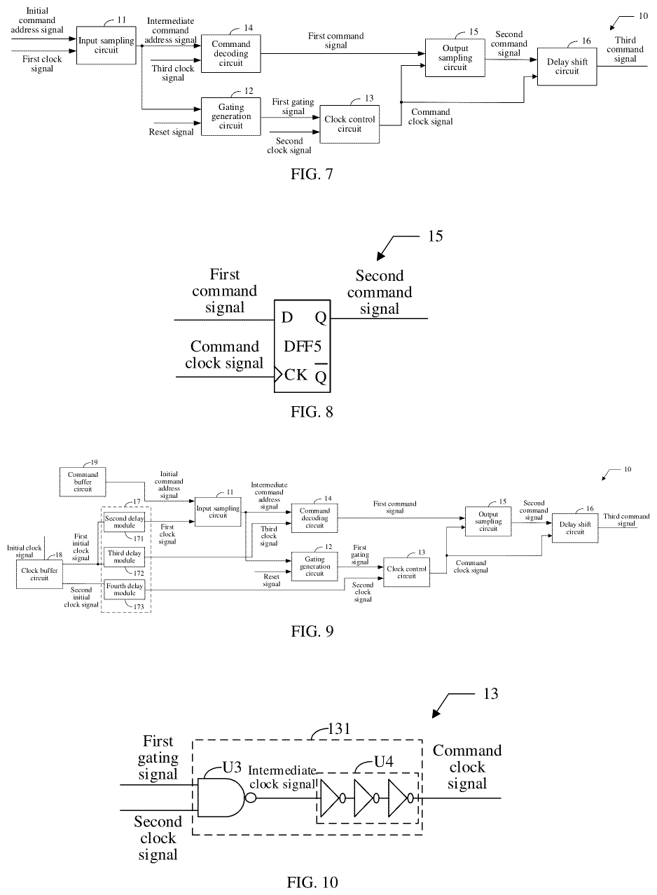

In some embodiments, based on the control circuit 10 shown in FIG. 3, and referring to FIG. 7, the control circuit 10 may further include an output sampling circuit 15 and a delay shift circuit 16.

The output sampling circuit 15 is configured to receive a first command signal and a command clock signal and perform sampling processing on the first command signal based on the command clock signal to obtain a second command signal.

The delay shift circuit 16 is configured to perform sampling and shifting processing on the second command signal to obtain a third command signal. The third command signal is used to control the resistance switching of the termination resistance.

It should be noted that in the embodiment of the present disclosure, the pulse width of the third command signal is widened compared to the second command signal.

It should be further noted that in the embodiment of the present disclosure, the command clock signal is generated through the clock control circuit 13, and the first command signal is generated through the command decoding circuit 14. Then, by sampling the first command signal based on the command clock signal, the second command signal can be generated. By sampling and shifting the second command signal, the third command signal can be generated for controlling the resistance switching of the termination resistance.

It should be further noted that in the embodiment of the present disclosure, the pulse width difference between the third command signal and the second command signal has an association relationship with the on die termination compensation value set by the controller.

Here, to ensure reduced reflection at the DQ pin when receiving DQ data, the pulse width of the third command signal needs an additional compensation amount (ODT_offset). ODT_offset is determined based on the instruction sent by the CPU and is used to further widen the pulse width of the ODT command. That is, at this point, the delay shift circuit 16 can further widen the pulse width of the ODT command based on the ODT_offset required by the CPU to generate the final ODT pulse at the DQ pin, i.e., the third command signal here. The pulse width difference between the third command signal and the second command signal may be represented as ODT_offset, and different on die termination compensation values may be set through the controller. In addition, ODT_offset may have nine possible values ranging from 0-8 tck, which is not specifically limited herein.

It should be further noted that in the embodiment of the present disclosure, the command clock signal is only related to the level state of the first gating signal. Specifically, when the first gating signal is in a high-level state, the frequency of the command clock signal is the same as that of the second clock signal; when the first gating signal is in a low-level state, the command clock signal is at a low level. Here, the delay shift circuit 16 also needs to receive the command clock signal, and when the ODT command is in a non-operational state, since the command clock signal is at a low level, the current can be further saved.

Furthermore, in some embodiments, for the output sampling circuit 15, referring to FIG. 8, the output sampling circuit 15 may include an output flip-flop DFF5.

A clock terminal of the output flip-flop DFF5 is configured to receive a command clock signal, an input terminal of the output flip-flop DFF5 is configured to receive a first command signal, and a first output terminal of the output flip-flop DFF5 is configured to output a second command signal.

The first output terminal of the output flip-flop DFF5 is configured to reflect a value at the input terminal of the output flip-flop DFF5 after being sampled by the command clock signal.

It should be noted that in the embodiment of the present disclosure, the output flip-flop DFF5 may be a D flip-flop.

It should be further noted that in the embodiment of the present disclosure, the first output terminal of the output flip-flop DFF5 serves as the output terminal of the output sampling circuit 15 for outputting the second command signal.

In some embodiments, based on the control circuit 10 shown in FIG. 7, and referring to FIG. 9, the control circuit 10 may further include a clock delay circuit 17, and the clock delay circuit 17 includes a second delay module 171, a third delay module 172, and a fourth delay module 173.

The second delay module 171 is configured to receive a first initial clock signal and perform second delay processing on the first initial clock signal to obtain a first clock signal.

The third delay module 172 is configured to receive the first initial clock signal and perform third delay processing on the first initial clock signal to obtain a third clock signal.

The fourth delay module 173 is configured to receive a second initial clock signal and perform fourth delay processing on the second initial clock signal to obtain a second clock signal.

It should be noted that in the embodiment of the present disclosure, the second delay module 171 may be represented by G2, and the delay time corresponding to the second delay processing is also represented by G2; the third delay module 172 may be represented by G4, and the delay time corresponding to the third delay processing is also represented by G4; the fourth delay module 173 may be represented by Ga, and the delay time corresponding to the fourth delay processing is also represented by Ga.

It should be further noted that in the embodiment of the present disclosure, the clock cycles of the first initial clock signal, the second initial clock signal, the first clock signal, the second clock signal, and the third clock signal are equal.

It should be further noted that in the embodiment of the present disclosure, different delay processing of the first initial clock signal can result in the first clock signal and the third clock signal, respectively. That is, after passing through the second delay module 171 and the third delay module 172, the first initial clock signal can yield a first clock signal and a third clock signal, each with a different delay time. The second delay processing and the third delay processing are distinct, and there is a temporal precedence between the first clock signal and the third clock signal.

It should be further noted that in the embodiment of the present disclosure, the first clock signal serves as a clock source for the input sampling circuit 11 to perform sampling processing on the initial command address signal, and the third clock signal serves as a clock source for the sampling sub-module within the command decoding circuit 14 to perform sampling processing on the decoded signal. The first clock signal performs sampling processing on the initial command address signal through the input sampling circuit 11, generating an intermediate command address signal, the intermediate command address signal undergoes second decoding processing by the decoding module in the command decoding circuit 14 to obtain a decoded signal, and the third clock signal, through the sampling sub-module in the command decoding circuit 14, performs sampling processing on the decoded signal to obtain an intermediate command signal. As a result, the delay times corresponding to the second delay processing and the third delay processing need to ensure that the fourth flip-flop DFF4 satisfies the setup time.

Furthermore, in some embodiments, as shown in FIG. 9, the control circuit 10 may further include a clock buffer circuit 18.

The clock buffer circuit 18 is configured to receive an initial clock signal and generate a first initial clock signal and a second initial clock signal based on the initial clock signal.

The frequency and the phase of the first initial clock signal are the same as the frequency and the phase of the second initial clock signal.

It should be noted that in the embodiment of the present disclosure, the first initial clock signal and the second initial clock signal are two clock signals with identical waveforms. Here, dividing the initial clock signal into two clock signals with identical waveforms can reduce the load of clock transmission and improve the clock quality.

It should be further noted that in the embodiment of the present disclosure, after generating the first initial clock signal and the second initial clock signal through the clock buffer circuit 18, a first clock signal and a third clock signal can be generated based on the first initial clock signal, and a second clock signal can be generated based on the second initial clock signal.

Furthermore, in some embodiments, as shown in FIG. 9, the control circuit 10 may further include a command buffer circuit 19. The command buffer circuit 19 is configured to provide an initial command address signal.

Furthermore, in some embodiments, for the clock control circuit 13, referring to FIG. 10, the clock control circuit 13 may include a fifth delay module 131.

The fifth delay module 131 is configured to receive a first gating signal and a second clock signal and perform a NAND logic operation and fifth delay processing on the first gating signal and the second clock signal to obtain a command clock signal.

It should be noted that in the embodiment of the present disclosure, the clock control circuit 13 performs control processing on the second clock signal based on the first gating signal and performs, when the first gating signal is in a first level state, a NAND logic operation and fifth delay processing on the second clock signal to generate the command clock signal. In addition, when the first gating signal is in the first level state, the clock cycles of the command clock signal and the second clock signal are equal.

It should be further noted that in the embodiment of the present disclosure, the clock control circuit 13 can control the release of the command clock signal. Specifically, when an ODT command arrives, that is, the ODT circuit is in an operational state, the clock control circuit 13 releases the command clock signal. When no ODT command arrives, that is, the ODT circuit is in a non-operational state, the clock control circuit 13 blocks the second clock signal so that the command clock signal is at a low level, i.e., does not release the command clock signal.

It should be further noted that in the embodiment of the present disclosure, the fifth delay module 131 may be represented by Gb, and the delay time corresponding to the fifth delay processing is also represented by Gb.

Furthermore, in some embodiments, for the fifth delay module 131, as shown in FIG. 10, the fifth delay module 131 includes a third NAND gate U3 and an inverting module U4.

A first input terminal of the third NAND gate U3 is configured to receive a first gating signal, a second input terminal of the third NAND gate U3 is configured to receive a second clock signal, and an output terminal of the third NAND gate U3 is configured to output an intermediate clock signal.

An input terminal of the inverting module U4 is connected to the output terminal of the third NAND gate U3 for performing delay and inversion processing on the intermediate clock signal and outputting a command clock signal through an output terminal of the inverting module U4.

It is understandable that in some embodiments, the inverting module U4 is composed of an odd number of NOT gates connected in series.

It should be noted that in the embodiment of the present disclosure, the inverting module U4 may be composed of one NOT gate, or composed of three, five, seven, etc., NOT gates connected in series, which is not specifically limited in the embodiments of the present disclosure. Exemplarily, in FIG. 10, the specific implementation of the embodiment of the present disclosure is described in detail by taking the example where the inverting module U4 is composed of three NOT gates connected in series.

It should be further noted that in the embodiment of the present disclosure, since the inverting module U4 includes an odd number of NOT gates, the intermediate clock signal is not only delayed but also undergoes a change in the level state compared to the intermediate clock signal. In addition, the delay time between the input intermediate clock signal and the output command clock signal of the inverting module U4 is related to the specific number of NOT gates in the inverting module U4. Different numbers of NOT gates in the inverting module U4 result in different delay times between the input intermediate clock signal and the output command clock signal of the inverting module U4. In this way, in the embodiment of the present disclosure, the specific number of NOT gates in the inverting module U4 can be determined based on the required delay time.

The embodiment of the present disclosure provides a control circuit, which includes: an input sampling circuit, configured to perform sampling processing on an initial command address signal based on a first clock signal to generate an intermediate command address signal; a gating generation circuit, configured to generate a first gating enable signal based on the intermediate command address signal and perform pulse width adjustment on the first gating enable signal based on a reset signal to generate a first gating signal; and a clock control circuit, configured to perform control processing on a second clock signal based on the first gating signal to generate a command clock signal. There is an association relationship between the level state of the first gating enable signal and the intermediate command address signal. When the first gating signal is in a first level state, the frequency of the command clock signal is the same as that of the second clock signal; when the first gating signal is in a second level state, the second clock signal is blocked so that the command clock signal is at a low level. In this way, since the level state of the first gating enable signal only has an association relationship with the intermediate command address signal, the first gating enable signal is no longer affected by the chip select signal, and at the same time, the intermediate command address signal can also determine whether the ODT command is in an operational state, such that the first gating signal is in the first level state only when the ODT command is in operation, during which the frequency of the command clock signal is the same as that of the second clock signal. When the ODT command is in a non-operational state, the first gating signal at this point is in a second level state, allowing the second clock signal to be blocked so that the command clock signal is at a low level. This can avoid the phenomenon of constant level switching of a logic gate in an ODT circuit when the ODT command is not needed, thereby effectively preventing extra current consumption, achieving the purpose of saving current and reducing memory power consumption, and ultimately improving memory performance.

In another embodiment of the present disclosure, for the first gating enable signal, the first gating enable signal can also be generated by a chip select (CS) signal. For clarity, the gating enable signal generated by the chip select signal is herein referred to as the “second gating enable signal” and may be represented by CS_MASK_Gating_EN. Specifically, when the chip select signal is in a low-level state, i.e., CS=0, the second gating enable signal is in a high-level state, i.e., CS_MASK_Gating_EN=1. In this case, the clock signal related to the ODT command is no longer blocked, and the clock-related logic gate in the ODT circuit will be subject to continuous level switching. When the chip select signal is in a high-level state, i.e., CS=1, the second gating enable signal is in a low-level state, i.e., CS_MASK_Gating_EN=0. In this case, the clock signal related to the ODT command is turned off, the clock signal related to the ODT command is blocked in the ODT circuit, and the clock-related logic gate in the ODT circuit will not be subject to level switching. Here, the chip select (CS) signal is used to generate the second gating enable signal to control the clock-related logic gate in the ODT circuit. However, when there is no ODT command, and the chip select signal is in a low-level state, the clock-related logic gate in the ODT circuit still undergoes level switching. This will consume a large amount of current and power.

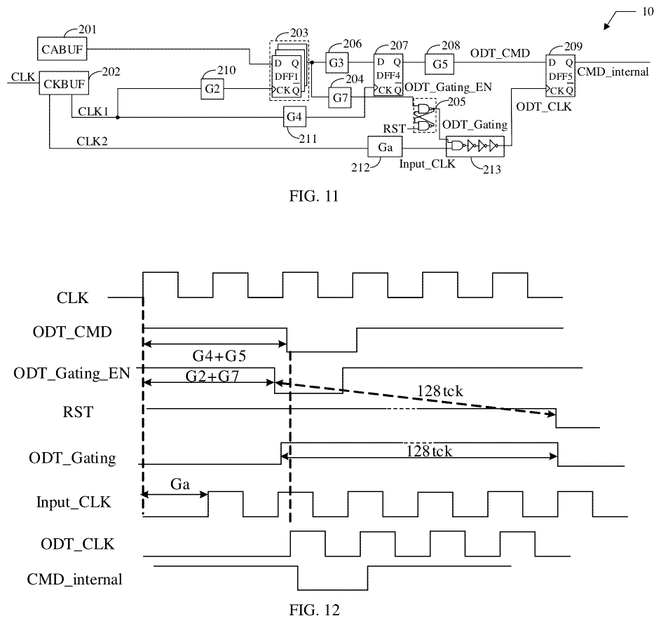

Based on this, a control circuit 10 is provided according to the embodiments of the present disclosure. By further refining the control circuit 10 of the previous embodiments, specifically referring to FIG. 11, the control circuit 10 may include a command buffer circuit 201, a clock buffer circuit 202, an input sampling circuit 203, a decoding sub-circuit 204, an SR latch 205, a decoding module 206, a fourth flip-flop 207, a first delay module 208, an output flip-flop 209, a second delay module 210, a third delay module 211, a fourth delay module 212, and a fifth delay module 213. Specifically, the gating generation circuit is composed of the decoding sub-circuit 204 and the SR latch 205; the command decoding circuit is composed of the decoding module 206, the fourth flip-flop 207, and the first delay module 208; the output sampling circuit is composed of the output flip-flop 209; the clock delay circuit is composed of the second delay module 210, the third delay module 211, and the fourth delay module 212; the clock control circuit is composed of the fifth delay module 213. For detailed connection relationships, refer to FIG. 11. It should be noted that here, as an example, the input sampling circuit 203 includes a first flip-flop, a second flip-flop, and a third flip-flop, which is not specifically limited.

It should be noted that in the embodiment of the present disclosure, the initial clock signal may be represented by CLK, the first initial clock signal may be represented by CLK1, the second initial clock signal may be represented by CLK2, the second clock signal may be represented by Input_CLK, the command clock signal may be represented by ODT_CLK, the first gating enable signal may be represented by ODT_Gating_EN, the first gating signal may be represented by ODT_Gating, the reset signal may be represented by RST, the first command signal may be represented by ODT_CMD, and the second command signal may be represented by CMD_internal.

It should be further noted that in the embodiment of the present disclosure, the command buffer circuit 201 may be represented by CABUF; the clock buffer circuit 202 may be represented by CKBUF; the first delay module 208 may be represented by G5, where G5 also represents the delay time corresponding to the first delay processing; the second delay module 210 may be represented by G2, where G2 also represents the delay time corresponding to the second delay processing; the third delay module 211 may be represented by G4, where G4 also represents the delay time corresponding to the third delay processing; the fourth delay module 212 may be represented by Ga, where Ga also represents the delay time corresponding to the fourth delay processing; the fifth delay module 213 may be represented by Gb, where Gb also represents the delay time corresponding to the fifth delay processing; the decoding sub-circuit 204 may be represented by G7, where G7 also represents a preset delay time.

Based on the control circuit 10 shown in FIG. 11, when the ODT command is in operation, the corresponding signal timing thereof may be as shown in FIG. 12. As shown in FIG. 12, the CLK2 signal undergoes the fourth delay processing by the fourth delay module 212, and the delay time between the Input_CLK signal and the CLK2 signal is Ga. Similarly, the CLK1 signal undergoes the third delay processing by the third delay module 211, then samples the decoded signal to obtain an intermediate command signal, and subsequently undergoes the first delay processing by the first delay module 208 to obtain the ODT_CMD signal. The delay time between the ODT_CMD signal and the CLK1 signal is G4+G5. The CLK1 signal undergoes the second delay processing by the second delay module 210 and the first decoding processing by the decoding sub-circuit 204, and the delay time between the ODT_Gating_EN signal and the CLK1 signal is G2+G7. In addition, based on the RST signal, pulse width adjustment is performed on the ODT_Gating_EN signal, and the pulse width of the ODT_Gating signal is 128 tck.

It should be further noted that in the embodiment of the present disclosure, as shown in FIG. 12, when the ODT_Gating signal is in a low-level state, the ODT_CLK signal is at a low level; when the ODT_Gating signal is in a high-level state, the frequency of the ODT_CLK signal is the same as that of the Input_CLK signal.

It should be further noted that in some embodiments, as shown in FIG. 12, the sum of the delay time corresponding to the first delay processing and the delay time corresponding to the third delay processing is greater than the sum of the preset delay time, the delay time corresponding to the second delay processing, and the delay time corresponding to the fifth delay processing, such that the time when the command clock signal reaches the output flip-flop is earlier than the time when the first command signal reaches the output flip-flop.

It is understandable that in the embodiment of the present disclosure, G4+G5>G2+G7+Gb. When G4+G5>G2+G7+Gb, in the output sampling circuit, the time interval between the falling edge of the first command signal ODT_CMD and the rising edge of the command clock signal ODT_CLK satisfies the setup time of the output flip-flop 209. That is, the time interval between when the first command signal ODT_CMD reaches the output flip-flop 209 and when the command clock signal ODT_CLK reaches the output flip-flop 209 needs to satisfy the setup time of the output flip-flop 209, such that the command clock signal ODT_CLK can perform sampling processing on the first command signal ODT_CMD when the first command signal ODT_CMD is in an active state.

It should be noted that in the embodiment of the present disclosure, the setup times of different flip-flops are different, and the setup time for each flip-flop is related to the respective design and process.

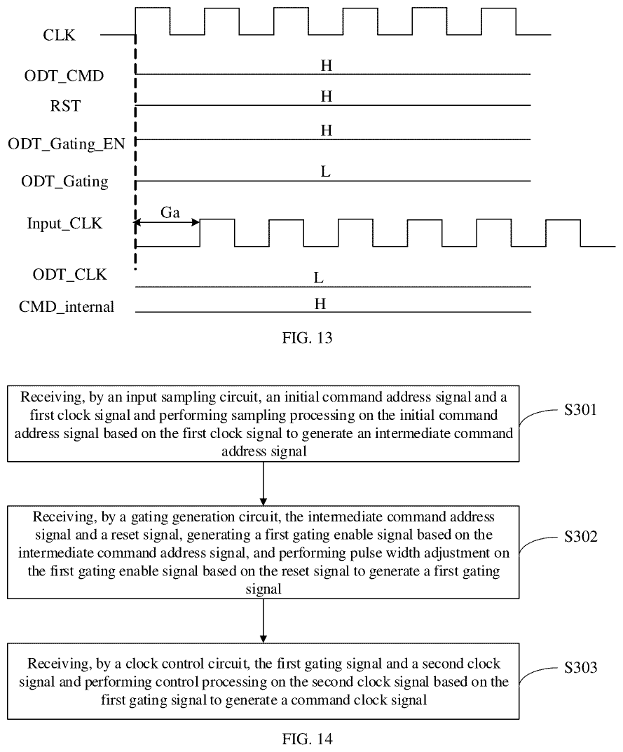

Based on the control circuit 10 shown in FIG. 11, when the ODT command is not in operation, the corresponding signal timing thereof may be as shown in FIG. 13. As shown in FIG. 13, the CLK2 signal undergoes the fourth delay processing by the fourth delay module 212, and the delay time between the Input_CLK signal and the CLK2 signal is Ga. When the ODT command is not in operation, the ODT_CMD signal is in a high-level state, the ODT_Gating_EN signal is in a high-level state, the RST signal is in a high-level state, and the ODT_Gating signal, obtained by passing the ODT_Gating_EN signal and the RST signal through the SR latch 205, is in a low-level state. When the ODT_Gating signal is in a low-level state, the Input_CLK signal is blocked, such that the ODT_CLK is at a low level, and thus the CMD_internal is in a high-level state.

It should be noted that in the embodiment of the present disclosure, because the frequency and phase of the CLK signal, the CLK1 signal, and the CLK2 signal are equal, the signal timing of the CLK signal, the CLK1 signal, and the CLK2 signal in FIGS. 12 and 13 is uniformly represented by the CLK signal.

It should be further noted that for the command clock signal related to the ODT command, the second gating enable signal generated by the chip select signal controls the command clock signal. Although this can prevent current consumption caused by the command clock signal, the clock-related logic gate in the ODT circuit still undergoes level switching when no ODT command arrives. However, in the embodiment of the present disclosure, the first gating enable signal, generated by the initial command address signal (which, for example, may include a first initial command address signal CA0, a second initial command address signal CA1, and a third initial command address signal CA2), controls the command clock signal. This allows the command clock signal to be released upon the arrival of an ODT command, but keeps the command clock signal at a low level when no ODT command arrives, thereby saving current. That is, in the embodiment of the present disclosure, because the chip select signal is no longer used as a gating (Gating) signal, the level switching of the clock-related logic gate in the ODT circuit is independent of the chip select signal. Therefore, when no ODT command arrives and the chip select signal is in a low-level state, the clock-related logic gate in the ODT circuit will no longer undergo level switching, thus avoiding additional current consumption and saving current.

The embodiments of the present disclosure provide a control circuit, and a detailed explanation of the specific implementation of the previous embodiments is provided based on the above embodiment. It can be seen that in the control circuit 10, an initial command address signal, formed by combining CA0/CA1/CA2 signals related to the ODT command, is used to generate a first gating signal. The first gating signal only releases the clock when an ODT command arrives, thereby saving a significant amount of current and achieving the purpose of reducing power consumption.

In yet another embodiment of the present disclosure, referring to FIG. 14, a schematic flowchart of a control method according to an embodiment of the present disclosure is illustrated. As shown in FIG. 14, the method may include:

In S301, an initial command address signal and a first clock signal are received through an input sampling circuit, and sampling processing is performed on the initial command address signal based on the first clock signal to generate an intermediate command address signal.

In S302, the intermediate command address signal and a reset signal are received through a gating generation circuit, a first gating enable signal is generated based on the intermediate command address signal, and pulse width adjustment is performed on the first gating enable signal based on the reset signal to generate a first gating signal.

In S303, the first gating signal and a second clock signal are received through a clock control circuit, and control processing is performed on the second clock signal based on the first gating signal to generate a command clock signal.

In the embodiment of the present disclosure, the pulse width of the first gating signal is greater than that of the first gating enable signal. There is an association relationship between the level state of the first gating enable signal and the intermediate command address signal. Moreover, when the first gating signal is in a first level state, the frequency of the command clock signal is the same as that of the second clock signal; when the first gating signal is in a second level state, the second clock signal is blocked so that the command clock signal is at a low level.

In the embodiment of the present disclosure, the method specifically pertains to a control method for an input clock related to an ODT command, and the method is applied to the control circuit 10 in the previous embodiments. For details not disclosed in the embodiment of the present disclosure, please refer to the description of the previous embodiments for understanding.

The embodiment of the present disclosure provides a control method. Since the level state of the first gating enable signal only has an association relationship with the intermediate command address signal, the first gating enable signal is no longer affected by the chip select signal, and at the same time, the intermediate command address signal can also determine whether the ODT command is in an operational state, such that the first gating signal is in the first level state only when the ODT command is in operation, during which the frequency of the command clock signal is the same as that of the second clock signal. When the ODT command is in a non-operational state, the first gating signal at this point is in a second level state, allowing the second clock signal to be blocked so that the command clock signal is at a low level. This can avoid the phenomenon of constant level switching of a logic gate in an ODT circuit when the ODT command is not needed, thereby effectively preventing extra current consumption, achieving the purpose of saving current and reducing memory power consumption, and ultimately improving memory performance.

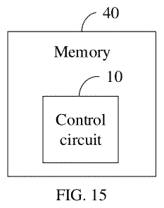

In still another embodiment of the present disclosure, referring to FIG. 15, a schematic diagram of a composition structure of a memory according to an embodiment of the present disclosure is illustrated. As shown in FIG. 15, the memory 40 may include the control circuit 10 according to any one of the previous embodiments.

In some embodiments, the memory 40 may include a DRAM chip. The DRAM chip may comply with not only the memory specifications such as DDR, DDR2, DDR3, DDR4, DDR5, and DDR6, but also the memory specifications such as LPDDR, LPDDR2, LPDDR3, LPDDR4, LPDDR5, and LPDDR6, which is not specifically limited herein.

In the embodiments of the present disclosure, for the memory 40, since the level state of the first gating enable signal only has an association relationship with the intermediate command address signal, the first gating enable signal is no longer affected by the chip select signal, and at the same time, the intermediate command address signal can also determine whether the ODT command is in an operational state. When the ODT command is in a non-operational state, the first gating signal at this point is in a second level state, allowing the second clock signal to be blocked so that the command clock signal is at a low level. This can avoid the phenomenon of constant level switching of a logic gate in an ODT circuit when the ODT command is not needed, thereby effectively preventing extra current consumption, achieving the purpose of saving current and reducing memory power consumption, and ultimately improving memory performance.

The above descriptions are merely preferred embodiments of the present disclosure and are not intended to limit the protection scope of the present disclosure.

It should be noted that in the present disclosure, the terms “include”, “comprise”, or any other variants thereof are intended to cover non-exclusive inclusion, such that a process, a method, an item, or an apparatus including a series of elements includes not only those elements but also other elements not explicitly listed, or elements inherent to such process, method, item, or apparatus. Without further limitation, an element defined by the phrase “including a . . . ” does not exclude the presence of additional identical elements in the process, method, item, or apparatus that includes the element.

The serial numbers of the embodiments of the present disclosure described above are for the purpose of describing only and do not represent the superiority or inferiority of the embodiments.

The methods disclosed in the method embodiments provided in the present disclosure may be combined in any manner without conflict to obtain new method embodiments.

The features disclosed in the product embodiments provided in the present disclosure may be combined in any manner without conflict to obtain new product embodiments.

The features disclosed in the method or device embodiments provided in the present disclosure may be combined in any manner without conflict to obtain new method or device embodiments.

The above description is only the specific embodiments of the present disclosure, but the protection scope of the present disclosure is not limited thereto; changes or substitutions that any of those skilled in the art can easily think of within the technical scope disclosed by the present disclosure shall all fall within the protection scope of the present disclosure. Therefore, the protection scope of the present disclosure shall be subject to the protection scope of the claims.

What is claimed is:

1. A control circuit, comprising an input sampling circuit, a gating generation circuit, and a clock control circuit, wherein:
the input sampling circuit is configured to receive an initial command address signal and a first clock signal and perform sampling processing on the initial command address signal based on the first clock signal to generate an intermediate command address signal;
the gating generation circuit is configured to receive the intermediate command address signal and a reset signal, perform first decoding processing on the intermediate command address signal to obtain a first gating enable signal, and perform pulse width adjustment on the first gating enable signal based on the reset signal to generate a first gating signal, a pulse width of the first gating signal being greater than a pulse width of the first gating enable signal; and
the clock control circuit is configured to receive the first gating signal and a second clock signal and perform control processing on the second clock signal based on the first gating signal to generate a command clock signal,
wherein if it is determined, based on the intermediate command address signal, that a first command is present, a level state of the first gating enable signal is at a low level; if it is determined, based on the intermediate command address signal, that the first command is not present, the level state of the first gating enable signal is at a high level, wherein the first command comprises at least one of following: a mode register read command (MRR), a write command (WR), a write with auto pre-charge command (WRA), and a read command (RD); additionally, when the first gating signal is in a first level state, frequency of the command clock signal is the same as frequency of the second clock signal; when the first gating signal is in a second level state, the second clock signal is blocked so that the command clock signal is at a low level.

2. The control circuit according to claim 1, wherein the first level state is a high-level state, and the second level state is a low-level state.

3. The control circuit according to claim 1, wherein the gating generation circuit comprises a decoding sub-circuit and an SR latch, wherein:
the decoding sub-circuit is configured to receive the intermediate command address signal and perform the first decoding processing on the intermediate command address signal to obtain the first gating enable signal, the first gating enable signal having a preset delay time compared to the intermediate command address signal; and
the SR latch is configured to receive the first gating enable signal and the reset signal and perform pulse width adjustment on the first gating enable signal based on the reset signal to generate the first gating signal.

4. The control circuit according to claim 3, wherein the SR latch comprises a first NAND gate and a second NAND gate, wherein:
a first input terminal of the first NAND gate is configured to receive the first gating enable signal, and a second input terminal of the first NAND gate is connected to an output terminal of the second NAND gate; a first input terminal of the second NAND gate is connected to an output terminal of the first NAND gate, and a second input terminal of the second NAND gate is configured to receive the reset signal; the output terminal of the first NAND gate is configured to output the first gating signal.

5. The control circuit according to claim 3, further comprising a command decoding circuit, wherein:
the command decoding circuit is configured to receive the intermediate command address signal and a third clock signal, perform second decoding processing on the intermediate command address signal to obtain a decoded signal, and perform sampling and delay processing based on the third clock signal and the decoded signal to obtain a first command signal.

6. The control circuit according to claim 5, wherein the command decoding circuit comprises a decoding module, a sampling sub-module, and a first delay module; additionally, an output terminal of the decoding module is connected to an input terminal of the sampling sub-module, and an output terminal of the sampling sub-module is connected to an input terminal of the first delay module, wherein:
the decoding module is configured to receive the intermediate command address signal and perform the second decoding processing on the intermediate command address signal to obtain the decoded signal;
the sampling sub-module is configured to receive the decoded signal and the third clock signal and perform sampling processing on the decoded signal based on the third clock signal to obtain an intermediate command signal; and
the first delay module is configured to receive the intermediate command signal and perform first delay processing on the intermediate command signal to obtain the first command signal.

7. The control circuit according to claim 6, further comprising an output sampling circuit and a delay shift circuit, wherein:
the output sampling circuit is configured to receive the first command signal and the command clock signal and perform sampling processing on the first command signal based on the command clock signal to obtain a second command signal; and
the delay shift circuit is configured to perform sampling and shifting processing on the second command signal to obtain a third command signal, wherein the third command signal is used to control resistance switching of a termination resistance.

8. The control circuit according to claim 7, wherein the output sampling circuit comprises an output flip-flop, wherein:
a clock terminal of the output flip-flop is configured to receive the command clock signal, an input terminal of the output flip-flop is configured to receive the first command signal, and a first output terminal of the output flip-flop is configured to output the second command signal,
wherein the first output terminal of the output flip-flop is configured to reflect a value at the input terminal of the output flip-flop after being sampled by the command clock signal.

9. The control circuit according to claim 8, further comprising a clock delay circuit, the clock delay circuit comprising a second delay module, a third delay module, and a fourth delay module, wherein:
the second delay module is configured to receive a first initial clock signal and perform second delay processing on the first initial clock signal to obtain the first clock signal;
the third delay module is configured to receive the first initial clock signal and perform third delay processing on the first initial clock signal to obtain the third clock signal; and
the fourth delay module is configured to receive a second initial clock signal and perform fourth delay processing on the second initial clock signal to obtain the second clock signal.

10. The control circuit according to claim 9, further comprising a clock buffer circuit, wherein:
the clock buffer circuit is configured to receive an initial clock signal and generate the first initial clock signal and the second initial clock signal based on the initial clock signal,
wherein frequency and phase of the first initial clock signal are the same as frequency and phase of the second initial clock signal.

11. The control circuit according to claim 9, wherein the clock control circuit comprises a fifth delay module, wherein:
the fifth delay module is configured to receive the first gating signal and the second clock signal and perform a NAND logic operation and fifth delay processing on the first gating signal and the second clock signal to obtain the command clock signal.

12. The control circuit according to claim 11, wherein the fifth delay module comprises a third NAND gate and an inverting module, wherein:
a first input terminal of the third NAND gate is configured to receive the first gating signal, a second input terminal of the third NAND gate is configured to receive the second clock signal, and an output terminal of the third NAND gate is configured to output an intermediate clock signal; and
an input terminal of the inverting module is connected to the output terminal of the third NAND gate for performing delay and inversion processing on the intermediate clock signal and outputting the command clock signal through an output terminal of the inverting module.

13. The control circuit according to claim 12, wherein the inverting module is composed of an odd number of NOT gates connected in series.

14. The control circuit according to claim 13, wherein
a sum of a delay time corresponding to the first delay processing and a delay time corresponding to the third delay processing is greater than a sum of the preset delay time, a delay time corresponding to the second delay processing, and a delay time corresponding to the fifth delay processing, such that a time when the command clock signal reaches the output flip-flop is earlier than a time when the first command signal reaches the output flip-flop.

15. A memory, comprising the control circuit according to claim 1.
